(19) United States
(12) Patent Application Publication
(10) Pub. No.: US 2026/0333588 A1
(43) Pub. Date: Oct. 22, 2026

(54) CARBON-BASED DIRECT PLATING PROCESS

(71) Applicant: MacDermid, Incorporated, Waterbury, CT (US)

(72) Inventor: Roger Bernards, Goshen, CT (US)

(21) Appl. No.: 19/111,201

(22) PCT Filed: Sep. 29, 2022
(86) PCT No.: PCT/US2022/045146

§ 371 Date: Mar. 12, 2025

(51) Int. Cl. H05K 3/18; C25D 3/38; C25D 5/54; C25D 7/00; H05K 1/09; H05K 1/11; H05K 3/06; H05K 3/22; H05K 3/42

(52) U.S. Cl. CPC H05K 3/188; C25D 3/38; C25D 5/54; C25D 7/00; H05K 1/092; H05K 1/115; H05K 3/067; H05K 3/227; H05K 3/424; H05K 2201/0323; H05K 2203/0723; H05K 2203/143

(57) ABSTRACT

A method of preparing a non-conductive substrate to allow metal plating thereon and a two-part gel coating composition. The method includes the steps of a) contacting the non-conductive substrate with a conditioner comprising: a high molecular weight, conditioning agent; b) applying a carbon-based dispersion to the conditioned substrate, wherein the carbon-based dispersion comprises adhesive carbon or graphite particles dispersed in a liquid solution; and c) etching the non-conductive substrate. The adhesive carbon black or graphite particles in the liquid-carbon based dispersion have a small particle size and a tight particle size distribution

### FIELD OF THE INVENTION

The present invention relates generally to a carbon-based direct plating process for use in printed circuit board manufacturing.

### BACKGROUND OF THE INVENTION

Printed wiring boards (also known as printed circuit boards) are generally laminated materials comprising two or more plates of foils of copper, which are separated from each other by a layer of non-conducting material. Although copper is most typically used as the electroplating metal in printed wiring boards, other metals such as nickel, gold, palladium, silver and the like can also be electroplated. The non-conducting layer(s) generally comprise an organic material such as an epoxy resin impregnated with glass fibers, but may also comprise thermosetting resins, thermoplastic resin, and mixtures thereof, alone or in combination with reinforcing materials such as fiberglass and fillers. To accommodate additional circuits on the printed wiring board, additional metal (e.g., copper) layers may be sandwiched between layers of insulating material to produce a multilayer wiring board.

In many printed wiring board designs, the electrical pathway or pattern requires a connection between the separated metal layers (i.e., copper plates) at certain points in the pattern. This is usually accomplished by drilling holes at the desired locations through the laminate of copper plates and the non-conducting layer(s) and connecting the separate metal layers. Metallization of the through-hole walls is necessary to achieve connections between two metal circuit patterns on each side of a printed wiring board, and/or between the inner layer circuit patterns of a multilayer board.

While electroplating is a desirable method of depositing copper and other conductive metals on a surface, electroplating cannot be used to coat nonconductive surfaces, such as an untreated through-holes. It is therefore necessary to treat through-holes with a conductive material to make the through-holes amenable to electroplating.

One process for making through-holes electrically conductive involves physically coating them with a conductive film. The thus coated through-holes are conductive enough to electroplate, but typically are not conductive and sturdy enough to form the permanent electrical connection between the circuit layers at either end of the through-hole. So, the coated through-holes are electroplated to provide a permanent connection. Electroplating lowers the resistance of the through-holes to a negligible level that will not consume an appreciable amount of power or alter circuit characteristics.

Through-hole walls may be prepared for electroplating by means of a carbon-based process that utilizes a liquid carbon dispersion. The typical steps of this process are as follows:
1) Surfaces of the through-holes are drilled and deburred. In the case of multilayer printed circuit boards, the boards may also be subjected to a desmear or etchback operation to clean the inner copper interfacing surfaces of the through-holes.
2) The printed wiring board is optionally, but preferably, subjected to a precleaning process that involves applying a precleaner to surfaces of the printed wiring board to prepare the printed wiring board to receive the liquid carbon black dispersion thereon.
3) After the application of the cleaner, the printed wiring board is rinsed in water to remove excess cleaner from the board and is contacted with a conditioner solution. The conditioner solution ensures that substantially all of the through-hole wall surfaces are prepared to accept a continuous layer of the subsequently applied carbon-based dispersion.
4) A liquid carbon-based dispersion is applied to or contacted with the cleaned and conditioned printed wiring board. The preferred methods of applying the dispersion to the printed wiring board include immersion and spraying.
5) The carbon-covered printed wiring board is subjected to a step wherein substantially all (i.e., more than about 95% by weight) of the water in the applied dispersion is removed and a dried deposit containing carbon is left in the through-holes and on other exposed surfaces of the nonconducting layer. This drying step may be accomplished by various methods, including, for example, evaporation at room temperature, heating the printed wiring board for a period of time at an elevated temperature, an air knife, or other similar means generally known to those skilled in the art. To insure complete coverage of the through-hole walls, the steps of immersing the board in the liquid carbon dispersion and then drying may be repeated.
6) Thereafter, the metal portions of the substrate are aggressively etched with high spray pressures and high total etch amounts to sufficiently remove the dried carbon coating from the metal portions of the substrate. This microetch step performs two very desirable tasks simultaneously: (1) the microetch step removes substantially all excess carbon black or graphite material adhering to the outer copper plates or foils as well as exposed surfaces of copper inner plates or foils in a multilayer printed wiring board; and (2) the microetch step chemically cleans and microetches slightly the outer copper surfaces, thereby making the surfaces good bases for either dry film application or electrolytic deposition of copper when followed by mechanically scrubbing of the printed wiring board.

The mechanism by which this microetch step works is not by attacking the carbon material deposited on the copper foil directly, but rather by attacking exclusively the first few atomic layers of copper directly below which provides the adhesion for the coating. The carbon black or graphite coated printed wiring board is contacted with the microetch solution to “flake” off the carbon black or graphite from the copper surfaces which are then removed from the microetch bath by filtering or other similar means.

The basic steps of this process are described in more detail, for example, in U.S. Pat. No. 4,619,741, the subject matter of which is herein incorporated by reference in its entirety. Various modifications and refinements to this process are set forth in U.S. Pat. Nos. 4,622,107, 4,622,108, 4,631,117, 4,684,560, 4,718,993, 4,724,005, 4,874,477, 4,897,164, 4,964,959, 4,994,153, 5,015,339, 5,106,537, 5,110,355, 5,139,642, 5,143,592, 5,725,807, and 7,128,820, the subject matter of each of which is herein incorporated by reference in its entirety.

U.S. Pat. No. 4,897,164 to Piano et al. describes a process in which after the drying step, a dried deposit of carbon black in the through-holes is contacted with an aqueous solution of an alkali metal borate prior to microetching to remove loose or easily removable carbon black particles from the areas of the through-holes.

U.S. Pat. No. 4,964,959 to Piano et al. describes the addition of a conductive polymer or combinations thereof to the carbon black dispersion.

U.S. Pat. No. 4,994,153 to Piano et al. describes a process for treating tooling holes or slots which have been coated with a carbon black dispersion in a nonconductive material which comprises removing said carbon black with an aqueous solution containing: (a) an alkanolamine; (b) an anionic surfactant which is the neutralized addition product of maleic and/or fumaric acid and a poly(oxylated) alcohol; (c) a nonionic surfactant which is an aliphatic mono and/or diphosphate ester; and (d) an alkali or alkaline earth metal hydroxide.

U.S. Pat. No. 5,015,339 to Pendleton describes an electroplating pretreatment wherein nonconductive material is first contacted with an alkaline permanganate solution, then a neutralizer/conditioner solution and then a carbon black dispersion.

In a variation on this basic process, the carbon-coated wiring board is subjected to a fixing step prior to drying in order to remove excess carbon dispersion from the surface of the printed wiring board and to make the carbon dispersion more workable as described, for example, in U.S. Pat. Pub. No. 2010/0034965 to Retallick et al., the subject matter of which is herein incorporated by reference in its entirety. Fixing may be accomplished by a chemical fixing method or by a mechanical fixing method.

In chemical fixing, a fixing solution is applied to the surfaces that have been wetted with the carbon dispersion and the fixing solution removes excess carbon deposits, smoothing the carbon coating on the recess surfaces by eliminating lumps and making the coating more uniform. In physical fixing, the recesses or other surfaces of the substrate which have been wetted with the carbon dispersion are subjected to a mechanical force to remove excess deposits of the carbon coating before it is dried, such as with a fluid jet or an air jet. For example, a fluid or air jet may be used to contact the surfaces that have been coated with the carbon dispersion to blow away any excess accumulation of the carbon deposit and smooths the carbon coating on the recess surfaces by eliminating lumps and making the coating more uniform.

Once the carbon-coated printed wiring board has been microetched, the printed wiring board can be electroplated with a suitable conductive metal.

All of the processes described above include a step in which the carbon-covered printed wiring board is subjected to the removal of substantially all (i.e., more than about 95% by weight) of the water in the applied dispersion so that dried deposit containing carbon is left in the holes and on other exposed surfaces of the nonconducting layer prior to the microetching step. That is, in all of these process described above, the carbon-coated wiring board is dried prior to the microetching step.

The microetch frequently causes problems, particularly in plating in the area of the copper dielectric interface. In particular, etching the copper frequently also strips the carbon coating from the dielectric area directly adjacent to the copper, thereby creating an insulating barrier for electrical continuity in the subsequent electroplating step. This barrier may then lead to poor plating and defects such as voids, knit lines, and plating folds. To avoid such kinds of defects, a lower microetch step is desirable.

To adequately remove carbon black or graphite from the copper surfaces, large pumps, high pressures, large etch chambers, and/or aggressive etching chemistry must typically be employed to produce an acceptable result. In addition, it is also necessary that the equipment be cleaned often to reduce nodulation in the metal plating step for the carbon black or graphite that has been flaked off the copper surfaces.

It has also been discovered that carbon-based direct plate colloids/dispersions are prone to poor adhesion to the dielectric substrate due in part to size of the colloidal particles. A wide distribution of particle size can also contribute to poor adhesion due to the presence of larger-sized colloidal particles.

Thus, it would be desirable to provide a direct plating process that offers reduced nodulation and that also does not require additional processing steps or conditions to produce a good result. In addition, it would be desirable to provide a direct plating process that improves adhesion of the carbon dispersion to the printed wiring board substrate.

### SUMMARY OF THE INVENTION

It is an object of the present invention to provide an improved direct plating process for preparing a printed wiring board to accept electroplating thereon.

It is another object of the present invention to provide an improved direct plating process that is capable of reducing nodulation in the metal plating step.

It is still another object of the present invention to provide a direct plating process that improves electroplating conditions.

It is still another object of the present invention to provide a graphite or carbon black dispersion in which the carbon particles exhibit a smaller average particle size to enhance adhesion of the particles to the printed wiring board.

It is still another object of the present invention to provide a graphite or carbon black dispersion that has a tighter particle size distribution to enhance adhesion of the particles to the printed wiring board.

It is still another object of the present invention to provide a graphite or carbon black dispersion in which the graphite or carbon black particles are adhesive.

To that end, in one embodiment the present invention relates generally to a method of preparing a non-conductive substrate to allow metal plating thereon, the method comprising the steps of:
a) optionally, but preferably, contacting the non-conductive substrate with a precleaner;
b) contacting the non-conductive substrate with a conditioner comprising a high molecular weight conditioning agent;
c) applying a liquid carbon-based dispersion to the conditioned non-conductive substrate to form a carbon/conditioner gel coating on the conditioned non-conductive substrate, wherein the carbon-based dispersion comprises adhesive carbon black or graphite particles dispersed in a liquid solution, wherein the carbon particles coagulate onto the conditioned substrate to form a carbon/conditioner gel coating; and
d) etching the carbon/conditioner gel coated substrate;
wherein the adhesive carbon black or graphite particles in the liquid-carbon based dispersion have a small particle size and a tight particle size distribution.

In one embodiment, the present invention also relates generally to a two-part gel coating composition for preparing a non-conductive substrate to allow metal plating thereon, the two-part gel coating comprising:
a. a conditioner comprising:
   i. a polyquaternium compound having a molecular weight of greater than 1,000,000 g/mol;
   ii. a pH buffer; and
   iii. a surface tension reducing agent,
      wherein the conditioner has a pH in the range of about 8 to about 10; and
b. a liquid carbon-based dispersion, wherein the liquid carbon-based dispersion comprises:
   i. adhesive carbon or graphite particles dispersed in a dispersant, and
   ii. a pH adjuster,
      wherein the adhesive carbon black or graphite particles have a small particle size and a tight particle size distribution, and where the pH of the liquid carbon dispersion is in a range of about 8 to about 10;
wherein when the conditioner and the liquid carbon-based dispersion are sequentially applied to the non-conductive substrate, an adherent carbon/conditioner gel coating is formed on the surface of the non-conductive substrate.

### DETAILED DESCRIPTION OF THE PREFERRED EMBODIMENTS

The present invention relates generally to a carbon-based direct plating process for printed circuit board or printed wiring board manufacture.

As used herein, “a,” “an,” and “the” refer to both singular and plural referents unless the context clearly dictates otherwise.

As used herein, the term “about” refers to a measurable value such as a parameter, an amount, a temporal duration, and the like and is meant to include variations of +/−15% or less, preferably variations of +/−10% or less, more preferably variations of +/−5% or less, even more preferably variations of +/−1% or less, and still more preferably variations of +/−0.1% or less of and from the particularly recited value, in so far as such variations are appropriate to perform in the invention described herein. Furthermore, it is also to be understood that the value to which the modifier “about” refers is itself specifically disclosed herein.

As used herein, spatially relative terms, such as “beneath”, “below”, “lower”, “above”, “upper”, “front”, “back”, and the like, are used for ease of description to describe one element or feature's relationship to another element(s) or feature(s). It is further understood that the terms “front” and “back” are not intended to be limiting and are intended to be interchangeable where appropriate.

As used herein, the terms “comprises” and/or “comprising,” specify the presence of stated features, integers, steps, operations, elements, and/or components, but do not preclude the presence or addition of one or more other features, integers, steps, operations, elements, components, and/or groups thereof.

In one embodiment, the present invention relates generally to a method of preparing a non-conductive substrate to allow metal plating thereon, the method comprising the steps of:
a) optionally, but preferably, contacting the non-conductive substrate with a precleaner;
b) contacting the precleaned non-conductive substrate with a conditioner comprising a high molecular weight conditioning agent;
c) applying a liquid carbon-based dispersion to the precleaned and conditioned non-conductive substrate to form a carbon/conditioner gel coating on the conditioned non-conductive substrate, wherein the carbon-based dispersion comprises adhesive carbon black or graphite particles dispersed in a liquid solution, wherein the carbon particles coagulate onto the conditioned substrate to form a carbon/conditioner gel coating; and
d) etching the carbon/conditioner gel coated substrate;
wherein the adhesive carbon black or graphite particles in the liquid-carbon based dispersion have a small particle size and a tight particle size distribution.

In one embodiment, the present invention also relates generally to a two-part gel coating composition for preparing a non-conductive substrate to allow metal plating thereon, the two-part gel coating comprising:
c. a conditioner comprising:
   i. a polyquaternium compound having a molecular weight of greater than 1,000,000 g/mol;
   ii. a pH buffer; and
   iii. a surface tension reducing agent,
      wherein the conditioner has a pH in the range of about 8 to about 10; and
d. a liquid carbon-based dispersion, wherein the liquid carbon-based dispersion comprises:
   i. adhesive carbon or graphite particles dispersed in a dispersant, and
   ii. a pH adjuster,
      wherein the adhesive carbon black or graphite particles have a small particle size and a tight particle size distribution, and where the pH of the liquid carbon dispersion is in a range of about 8 to about 10;
wherein when the conditioner and the liquid carbon-based dispersion are sequentially applied to the non-conductive substrate, an adherent carbon/conditioner gel coating is formed on the surface of the non-conductive substrate.

In one embodiment, the non-conductive substrate is a printed wiring board or a printed circuit board substrate.

Once the etching step is performed and the liquid carbon coating dries on the non-conductive substrate to form a conductive carbon coating on the printed wiring board substrate, the printed wiring board substrate can be electroplated with a suitable metal.

The inventors of the present invention have discovered that an improved result can be obtained if the etching step is performed before the conductive carbon coating dries on the substrate.

Previously, it was believed that it was necessary to dry the conductive carbon coating on the surface prior to contacting the substrate with the etching solution. Thus, it had previously been understood that drying of the conductive carbon coating on the substrate surfaces was necessary prior to etching the substrate so as to allow the carbon particles to sufficiently adhere to the non-conductive portions of the substrate to facilitate electroplating of metal onto the non-conductive portions of the substrate. However, when the conductive carbon coating is dried before etching, the equipment can become contaminated with the carbon particles.

Thus, in one preferred embodiment, the etching step is performed before the liquid conductive carbon coating dries on the non-conductive substrate. In other words, the etching step is preferably performed prior to the drying step and without first drying the conductive carbon coating onto the surface.

Some of the benefits to performing the etching step prior to drying of the conductive carbon coating on the substrate include the following:
1) It is much easier to etch metal portions of the substrate to remove conductive carbon coating thereon if the etching step is performed prior to drying of the conductive carbon coating. While the dried conductive carbon coating layer acts as a barrier to etching the underlying metal, the wet conductive carbon coating layer does not significantly act as a barrier to etching;
2) The total etch amount and spray pressure needed to obtain clean metal portions of the substrate are greatly reduced if the substrate is etched before the conductive carbon coating is dried as compared with after the conductive carbon coating is dried; and
3) The cleanliness of the process and the equipment used to apply the conductive carbon coating is greatly improved because carbon particles are etched off the metal portions of the substrate in the chamber or tank immediately after the chamber or tank containing the carbon suspension/colloid. Normally, this means that the outer surface of the substrate is completely free of carbon such that the rollers and driers normally employed after the carbon suspension solution remain at least substantially free of carbon particles.

Collectively, the benefits of the process described herein also reduce the amount of nodulation that can occur in the subsequent metal plating step. In contrast, prior art process allowed for more carbon particles to remain on the metal portions of the substrate because of the difficulty in removing the particles in the etch step and due to carbon contamination from the dried carbon remaining on the equipment that can be redeposited onto the surface of the substrate.

In contrast, in the present invention, there is much reduced nodulation in the metal plating step because the wet carbon coating on the substrate is etched off of the metal portions of the substrate prior to drying the coating such that the carbon is removed from the metal portions of the substrate more completely. Thus, there is less opportunity for the equipment to redeposit dried carbon particles back onto the surface, resulting in greatly reduced nodule formulation in the metal plating step.

As described herein, in one embodiment, the printed wiring board is optionally, but preferably, contacted with a precleaner prior to the conditioning step. If used, a suitable precleaner comprises a standard acid cleaner for printed wiring boards, such as a solution of sulfuric acid and a nonionic surfactant, a commercial product of which is available from MacDermid Enthone Inc. under the tradename Acid Cleaner 6A. The printed wiring board may be subjected to the precleaner by immersing the printed wiring board into the precleaner (or otherwise contacting the printed wiring board with the precleaner) for a suitable time to remove debris and/or contaminants from the surface of the substrate. For example, the printed wiring board may be immersed into the precleaner for between 30 second and 5 minutes, more preferably between one minute and two minutes and at a temperature between about room temperature up to about 55° C.

Next, the printed wiring board is subjected to the conditioning step in which the substrate is contacted with a conditioner comprising a high molecular weight conditioning agent as described, for example in U.S. Pat. No. 10,986,738, the subject matter of which is herein incorporated by reference in its entirety. In one embodiment, the printed wiring board is contacted with the conditioner by immersing the printed wiring board in the conditioner at a suitable temperature and for a suitable amount of time.

In one embodiment, conditioner comprises a high molecular weight conditioning agent in which the molecular weight of the conditioning agent is greater than about 1,000,000 g/mol, more preferably greater than about 2,000,000 g/mol, even more preferably greater than about 3,000,000 g/mol. The printed wiring board substrate is contacted with the conditioner for at least 20 seconds. In one embodiment, the printed wiring board substrate is contacted with the conditioner for between about 20 seconds to about 5 minutes. In addition, the pH of the conditioner is generally between 1 and 14, more preferably between 7 and 14, more preferably between about 8 and about 10. In one embodiment, the conditioner is alkaline and pH of about 9 is suitable.

Examples of high molecular weight conditioning agents used in the conditioner described herein include, but are not limited to polyquaternium compounds with a molecular weight of greater than 1,000,000 or greater than 2,000,000 g/mol or greater than 3,000,000 g/mol. Polyquaternium is the International Nomenclature for cosmetic ingredients used in the personal care industry and is used to define structures containing quaternary ammonium centers in the polymer. Examples of polyquaternium compounds are recite below in Table 1. Other polyquaternium compounds and other similar structures having a molecular weight of greater than 1,000,000 g/mol would also be usable in the practice of the instant invention.

TABLE 1
Polyquaternium Compounds:

| Polyquaternium | Chemical Identity |
|---|---|
| Polyquaternium-1 | Ethanol, 2,2′,2″-nitrilotris-, polymer with 1,4-dichloro-2-butene and |
| | N,N,N′N′-tetramethyl-2-butene-1,4-diamine |
| Polyquaternium-2 | Poly[bis(2-chloroethyl) ether-alt-1,3-bis[3-(dimethylamino)propyl]urea] |
| Polyquaternium-4 | Hydroxyethyl cellulose dimethyl diallylammonium chloride copolymer; |
| | Diallyldimethylammonium chloride-hydroxyethyl cellulose copolymer |
| Polyquaternium-5 | Copolymer of acrylamide and quaternized dimethylammoniumethyl |
| | methacrylate |
| Polyquaternium-6 | Poly(diallyldimethylammonium chloride) |
| Polyquaternium-7 | Copolymer of acrylamide and diallyldimethylammonium chloride |
| Polyquaternium-8 | Copolymer of methyl and stearyl dimethylaminoethyl ester of |
| | methacrylic acid, quaternized with dimethylsulphate |
| Polyquaternium-9 | Homopolymer of N,N-(dimethylamino)ethyl ester of methacrylic acid, |
| | quaternized with bromomethane |
| Polyquaternium-10 | Quaternized hydroxyethyl cellulose |
| Polyquaternium-11 | Copolymer of vinylpyrrolidone and quaternized dimethylaminoethyl |
| | methacrylate |
| Polyquaternium-12 | Ethyl methacrylate / abietyl methacrylate / diethylaminoethyl |
| | methacrylate copolymer quaternized with dimethyl sulfate |
| Polyquaternium-13 | Ethyl methacrylate / oleyl methacrylate / diethylaminoethyl methacrylate |
| | copolymer quaternized with dimethyl sulfate |
| Polyquaternium-14 | Trimethylaminoethylmethacrylate homopolymer |
| Polyquaternium-15 | Acrylamide-dimethylaminoethyl methacrylate methyl chloride |
| | copolymer |
| Polyquaternium-16 | Copolymer of vinylpyrrolidone and quaternized vinylimidazole |
| Polyquaternium-17 | Adipic acid, dimethylaminopropylamine and dichloroethylether |
| | copolymer |
| Polyquaternium-18 | Azelaic acid, dimethylaminopropylamine and dichloroethylether |
| | copolymer |
| Polyquaternium-19 | Copolymer of polyvinyl alcohol and 2,3-epoxypropylamine |
| Polyquaternium-20 | Copolymer of polyvinyl octadecyl ether and 2,3-epoxypropylamine |
| Polyquaternium-22 | Copolymer of acrylic acid and diallyldimethylammonium chloride |
| Polyquaternium-24 | Quaternary ammonium salt of hydroxyethyl cellulose reacted with a |
| | lauryl dimethyl ammonium substituted epoxide |
| Polyquaternium-27 | Block copolymer of Polyquaternium-2 and Polyquaternium-17 |
| Polyquaternium-28 | Copolymer of vinylpyrrolidone and methacrylamidopropyl |
| | trimethylammonium |
| Polyquaternium-29 | Chitosan modified with propylen oxide and quaternized with |
| | epichlorhydrin |
| Polyquaternium-30 | Ethanaminium, N-(carboxymethyl)-N,N-dimethyl-2-[(2-methyl-1-oxo-2- |
| | propen-1-yl)oxy]-, inner salt, polymer with methyl 2-methyl-2- |
| | propenoate |
| Polyquaternium-31 | N,N-dimethylaminopropyl-N-acrylamidine quatemized with |
| | diethylsulfate bound to a block of polyacrylonitrile |
| Polyquaternium-32 | Poly(acrylamide 2-methacryloxyethyltrimethyl ammonium chloride) |
| Polyquaternium-33 | Copolymer of trimethylaminoethylacrylate salt and acrylamide |
| Polyquaternium-34 | Copolymer of 1,3-dibromopropane and N,N-diethyl-N′,N′-dimethyl-1,3- |
| | propanediamine |
| Polyquaternium-35 | Methosulphate of the copolymer of |
| | methacryloyloxyethyltrimethylammonium and of |
| | methacryloyloxyethyldimethylacetylammonium |
| Polyquaternium-36 | Copolymer of N,N-dimethylaminoethylmethacrylate and |
| | buthylmethacrylate, quaternized with dimethylsulphate |
| Polyquaternium-37 | Poly(2-methacryloxyethyltrimethylammonium chloride) |
| Polyquaternium-39 | Terpolymer of acrylic acid, acrylamide and diallyldimethylammonium |
| | Chloride |
| Polyquaternium-42 | Poly[oxyethylene(dimethylimino)ethylene (dimethylimino)ethylene |
| | dichloride] |
| Polyquaternium-43 | Copolymer of acrylamide, acrylamidopropyltrimonium chloride, 2- |
| | amidopropylacrylamide sulfonate and dimethylaminopropylamine |
| Polyquaternium-44 | 3-Methyl-1-vinylimidazolium methyl sulfate-N-vinylpyrrolidone |
| | copolymer |
| Polyquaternium-45 | Copolymer of (N-methyl-N-ethoxyglycine)methacrylate and N,N- |
| | dimethylaminoethylmethacrylate, quaternized with dimethyl sulphate |
| Polyquaternium-46 | Terpolymer of vinylcaprolactam, vinylpyrrolidone, and quaternized |
| | vinylimidazole |
| Polyquaternium-47 | Terpolymer of acrylic acid, methacrylamidopropyl trimethylammonium |
| | chloride, and methyl acrylate |

In addition to the high molecular weight conditioning agent, the conditioner may also comprise a pH buffer such as borax and optionally, but preferably, a surface tension reducing agent such as a nonionic surfactant, an example of which is available from Evonik Industries AG under the tradename Tomadol 91-6.

The temperature of the conditioner may be maintained at a temperature between room temperature and about 150° F., more preferably between about 80 and about 130° F., even more preferably between about 85 and about 110° F., or about 95° F. while the printed wiring board is being brought into contact with the conditioner.

The large molecular weight of the conditioning agent results in the formation of a gel when the carbon dispersion contacts and then coats the surface of the pre-adsorbed conditioner on the surface of the substrate. The graphite (or carbon black) that flocculates and the conditioner comprising the high molecular weight conditioning agent together form a gel-like solid-liquid coating that allows for the gel-like coating to be sprayed hard during the subsequent microetching step without rinsing away. The gel-like coating between the conditioner and graphite (or carbon black) coating forms because the conditioner is very high molecular weight and contains a polyquaternary compound and also because the carbon black or graphite particles are adhesive. The polyquaternary compound neutralizes the negative charge on the graphite (or carbon black) colloid and then the conditioner comprising the high molecular weight polyquaternary compound causes the resulting flocculant to be a gel-like solid-liquid coating that does not rinse off easily and can withstand the microetch step even though the carbon coating is not dried first.

Once conditioning step has been completed, the printed wiring board is contacted with a carbon-based dispersion as further described herein.

The carbon-based dispersion comprises a source of electrically conductive adhesive carbon particles and one or more binders and/or dispersants capable of dispersing the electrically conductive adhesive carbon particles. Preferred methods of applying the liquid carbon dispersion to the printed wiring board include immersion and spraying, as well as other methods of applying chemicals used in the printed circuit board industry. In preparing the liquid carbon-based dispersion, the ingredients, and any other preferred ingredients, are mixed together to form a stable dispersion. This may be accomplished by subjecting a concentrated form of the dispersion to wet grinding or milling to thoroughly mix the ingredients. Suitable wet grinding and milling processes include, for example ball milling, colloidal milling, high-shear milling, etc., ultrasonic techniques or other like procedures. What is important is that the wet grinding or milling technique is capable of producing a carbon dispersion having a small particle size and tight particle size distribution and is capable of producing adhesive carbon particles. While there are a number of ways to reduce the particle size of carbon based dispersions, it is also important that the particle size distribution be controlled. The dispersion can then be later diluted with water or other dispersant to the desired concentration for the working bath.

An important factor is consistency of the particle size and it is desired that the dispersion contain no large particles, such as particles having a diameter greater than 800 nm for carbon black and 3,500 nm for graphite. In addition, it is also desirable that the milling method produce consistent particle sizes for the dispersions of the present invention without the need for waste or and without the need for centrifuging.

So this combination of dispersant and/or binder choice and the milling process together make a much improved product that is easier to make, more efficient, less costly, more stable, less waste, and it sticks to the surface of the PCB much better such that it can be sprayed hard with micro etch solution before drying and still not wash off. In addition, while graphite and carbon black particles are generally thought of as being lubricating, the milling process of the instant invention surprisingly produces carbon black or graphite particles that are themselves adhesive/adherent. Thus, the adhesive carbon particles of the instant invention, when dispersed in the dispersant, are able to more firmly adhere to the substrate and thus do not easily wash off.

Unlike prior art processes in which the carbon-dispersion is dried prior to the microetch step, the gel-like solid-liquid coating formed by the carbon dispersion containing adhesive carbon black and/or graphite particles and the conditioner agent described herein is capable of withstanding high pressure spray before drying. This allows the adhesive carbon particles to cling more closely to the through-hole walls and to withstand the spray etch step, even before the coating is dried.

Controlling and/or reducing the particle size and the particle size distribution of carbon based colloids/dispersions has surprisingly shown to affect the adhesion of the carbon particles to the dielectric substrate of printed circuit boards. Making a colloid or dispersion that has a smaller particle size and a tighter particle size distribution than is currently available in the art surprisingly aids in the subsequent adhesion of the particles to the substrate in the direct plate process form making printed circuit boards conductive. This adhesion is especially better when processing the circuit boards with a direct plate process in which the etching step is performed before the coating is dried. Normally when such a wet carbon containing coating is spray etched before drying, the particles are sprayed off of the substrate and do not have sufficient adhesion.

The carbon-based colloid or dispersion comprises adhesive graphite or carbon black particles and in which the particles are reduced below a certain size. For carbon black containing colloid/dispersions, the particles are reduced to a D50 of less than 120 nm, preferably a D50 of less than 110 nm, more preferably a D50 of less than 100 nm, and a D99 of less than 400 nm, preferably a D99 of less than 300 nm, more preferably a D99 of less than 250 nm. For a graphite-containing colloid/dispersion, the particles are reduced to a D50 of less than 350 nm, preferably less than 325 nm, more preferably less than 300 nm and a D99 of less than 2500 nm, preferably a D99 of less than 2,000 nm, more preferably a D99 of less than 1,800 nm. This particle size was measured with a BLUEWAVE particle size analyzer, available from Microtrac MRB. The BLUEWAVE uses a laser diffraction analyzer to measure volume, number and area distributions of particles as well as percentiles.

Typically, small graphite particles exhibit a D50 of about 1,000 nm. However, the D50 of the graphite particles of the instant invention is significantly less, being on the order of less than 350 nm or less than 325 nm or less than 300 nm. This is due in part to the means of milling the graphite into smaller particles as well as the dispersant used therein.

Examples of the electrically conductive carbon usable in the carbon dispersion, include, for example, carbon black and graphite. Many types of carbon can be used, including, for example, carbon blacks, furnace blacks, and graphite.

In the case of carbon blacks, it is preferred to utilize carbon blacks which are initially acidic or neutral, i.e. those which have a pH of between about 1 and about 7.5, more preferably between about 2 and about 4 when slurried with water. Preferred carbon black particles are also very porous and generally have as their surface area from about 45 to about 1100, and preferably about 300 to about 600, square meters per gram, as measured by the BET method (method of Brunauer-Emmert-Teller).

Examples of some commercially available carbon blacks suitable for use in the present invention include Cabot XC-72R Conductive, Cabot Monarch 800, Cabot Monarch 1300 (all available from Cabot Corporation of Boston, Massachusetts). Other suitable carbon blacks include Columbian T-10189, Columbian Conductiex 975 Conductive, Columbian CC-40,220, and Columbian Raven 3500 (all available from Columbian Carbon Company of New York, New York). Suitable graphites include Showa-Denko UFG (available from Showa-Denko K.K., 13-9 Shiba Dmon 1-Chrome, Minato-Ku, Tokyo, 105 Japan), Nippon Graphite AUP (available from Nippon Graphite Industries, Ishiyama, Japan), and Asbury Micro 850 (available from Asbury Graphite Mills of Asbury, New Jersey).

The electrically conductive carbon particles should be present in an amount effective to provide an electrically conductive coating when the coating composition is applied to the substrate. The carbon may be present at a concentration within the range of about 0.1 to about 20% by weight, alternatively from about 0.5 to about 10% by weight, alternatively from about 1% to about 7% by weight, alternatively from greater than about 4% to about 6.5% by weight of the composition.

In one embodiment, the lower limit of the total concentration of solids in the coating composition is between about 1.5% by weight and about 5% by weight, more preferably between about 2.0% by weight and about 4.5% by weight solids, this value includes the graphite and/or carbon black particles themselves along with the dispersant and/or the one or more binders, and any buffers and/or pH modifiers, to produce a concentration of the total solids in the solution. The upper limit of the total concentration of solids in the coating composition is based in part on cost. Typically the upper limit of the total concentration of solids is about 10% by weight solids, more preferably no more than 5% by weight solids. In one embodiment, the total concentration of solids in the coating composition is in the range of no more than 3% by weight solids, or in the range of about 2.0 to about 2.5% by weight solids.

The normal percentage of graphite to other ingredients is about 50-60% by weight, so 1.5% by weight total solids would be 0.75% by weight graphite particles as an example. This ratio of graphite/carbon to other ingredients such as dispersants, binders, buffers pH adjusters, etc. can range from about 33% to 80% by weight of the total solids as graphite/carbon black.

A common binder and/or dispersant used in prior art carbon dispersions is a starch or polysaccharide such as corn starch, potato starch, dextrin, acacia gum etc. However, it has been found that the starch does not produce foam or lower surface tension of the solution and that it is also a poor dispersant for making small particles and tight particle size distribution and a stable colloid as described herein. While starches and polysaccharides are believed to help dried particles more effectively adhere to the surfaces of the non-conductive substrate, the inventors of the present invention have discovered that such starches and polysaccharides do not aid in making small particles and stable colloids in the process described herein. Also, compositions containing starch or other polysaccharide are more prone to bacteria or fungus growth than the compositions of the present invention. Therefore, in one embodiment, the carbon dispersions described herein do not contain any starches or polysaccharides or contain no more than trace amounts of any starches or polysaccharides.

The choice of dispersant and/or binders is an important feature of the instant invention. In one embodiment, the dispersant has a negative charge that imparts a negative charge to the particle which aids in stability. In addition, the carbon dispersion must also exhibit desirable traits, including a dispersant and/or binder material that will allow the carbon particles to coagulate onto the conditioned wall surface to form a gel-like carbon/conditioner coating.

In one embodiment, the dispersant comprises a wetting agent such as an anionic, nonionic or cationic surfactant (or combinations thereof such as amphoteric surfactants). The dispersant should be soluble, stable and preferably nonfoaming in the liquid carbon black dispersion. In general, for a polar continuous phase as in water, the surfactants should preferably have a high HLB number (8-18). The preferred type of surfactant will depend mainly on the pH of the dispersion.

If the total dispersion is alkaline (i.e., has an overall pH in the basic range), it is preferred to employ an anionic or nonionic surfactant. Anionic surfactants include, for example, sodium or potassium salts of naphthalene sulfonic acid such as DARVAN No. 1 (R. T. Vanderbilt Co.), ECCOWET LF (Eastern Color and Chemical), PETRO AA, PETRO ULF (Petro Chemical Co., Inc.), and AEROSOL OT (American Cyanamid). Other anionic surfactants include neutralized phosphate ester-type surfactants such as MAPHOS 55, 56, 8135, 60A, L6 (Mazer Chemicals Inc.). One preferred anionic surfactant for a liquid carbon black dispersion is MAPHOS 56. Suitable nonionic surfactants include ethoxylated nonyl phenols such as POLY-TERGENT B-series (Olin Corporation) or alkoxylated linear alcohols such as POLY-TERGENT SL-series (Olin Corporation).

If the total dispersion is acidic (i.e., has an overall pH in the acidic range), it is preferred to employ selected anionic surfactants or cationic surfactants. Examples of such anionic surfactants include, for example, the sodium or potassium salts of naphthalene sulfonic acid described above. Examples of suitable cationic surfactants include, for example, ceytl dimethyl benzyl ammonium chloride such as AMMONYX T (Onyx Chemical Corporation); an ethanolated alkylguanidine amine complex such as AEROSOL C-61 (American Cyanamid); lipocals; dodecyldiphenyl oxide disulfonic acid (DDODA) such as DOWFAX 2Al (Dow Chemical); a sodium salt of DDODA such as STRODEX (Dexter Chemical Corporation); and salts of complex organic phosphate esters. Examples of preferred surfactants include amphoteric potassium salts of a complex amino acid based on fatty amines such as MAFO 13 and cationic ethoxylated soya amines such as MAZEEN S-5 or MAZTREAT (Mazer Chemicals Inc.). Combinations of surfactants may be employed.

If used, the binding agent may be any natural or synthetic polymer, polymerizable monomer, or other viscous or solid material (or precursor thereof) that is capable of both adhering to the carbon particles and of receiving an anionic dispersing agent. Alternatively, the binding agent can be capable of dispersing the carbon particles to which it adheres in the aqueous medium of the dispersion. For example, the binding agent may be a water soluble or water dispersible material selected from the group consisting of mono- and polysaccharides (or, more broadly, carbohydrates) and anionic polymers.

Polysaccharide (which for the present purposes includes disaccharide and higher saccharide) binding agents contemplate for use herein include corn starch, other starches, and polysaccharide gums. Polysaccharide gums contemplated for use herein include agar, arabic, xanthan (for example, KELZAN industrial grade xanthan gum, available from the Kelco Div. of Merck & Co, Inc. of Rahway, N.J.), pectin, alginate, tragacanath, dextran, and other gums. Derivative polysaccharides contemplated for use herein include cellulose acetates, cellulose nitrates, methylcellulose, and carboxymethylcellulose. Hemi-cellulose polysaccharides contemplated for use herein include d-gluco-d-mannans, d-galacto-d-gluco-d-mannans, and others. As discussed above, in one embodiment, the carbon dispersion does not contain any starches or polysaccharides or contain no more than trace amounts of any starches or polysaccharides.

Anionic polymers contemplated herein include the alkylcelluloses or carboxyalkylcelluloses, their low- and medium-viscosity alkali metal salts (e.g. sodium carboxymethylcellulose, or “CMC”), cellulose ethers, and nitrocellulose. Examples of such anionic polymers include KLUCEL hydroxypropylcellulose; AQUALON CMC 7L sodium carboxymethylcellulose, and NATROSOL hydroxyethlylcellulose, which are all commercially available from Aqualon Company of Hopewell, VA; ethylcellulose, available from Hercules of Wilmington, Del.; METHOCEL cellulose ethers, available from Dow Chemical Co., Midland, Mich.; and nitrocellulose, which is also available from Hercules.

In one embodiment, the dispersant comprises an anionic surfactant such as ethoxylated phosphate esters, ethoxylated and propoxylated phosphate esters, ethoxylated tristyrylphenol phosphate esters, and combinations of one or more of the foregoing. Commercial products of these include, for example, POLYSTEP® TSP-16PE30, available from Stepan Company and Soprophor® FLK available from Solvay S.A. other examples of acceptable anionic surfactants include sodium or potassium salts of naphthalene sulfonic acid such as DARVAN No. 1 (commercially available from Eastern Color and Chemical), PETRO AA and PETRO ULE (commercially available from Petro Chemical Co., Inc.), and AEROSOL OT (commercially available from American Cyanamid). Preferred anionic surfactants include neutralized phosphate ester-type surfactants such as MAPHOS 55,56,8135, 60A and L6 (commercially available from BASF Chemical Co.). The surfactant should be soluble, stable and preferably non-foaming in the liquid carbon dispersion.

The dispersant is chosen so as to lower the surface tension and makes for a much more stable and smaller suspended particle. The inventors of the present invention believe that a suitable dispersant is one that is capable of attaching to the carbon particle through the milling process and additional dispersant is in solution. The dispersant also allows for the graphite (or carbon black) particles to stick to the printed wiring board.

In one embodiment, the conductive carbon black dispersion of the instant invention consists essentially of (a) an anionic surfactant or dispersant; (b) the adhesive carbon black and/or graphite particles; (c) a pH adjuster, wherein the pH adjuster is a hydroxide; (d) a binder, wherein the binder does not include a starch or polysaccharide; and (e) balance water, wherein the adhesive carbon black and/or graphite particles are milled in a milling process capable of producing small particle size and a tight particle size distribution of the carbon particles. In one embodiment, the conductive carbon black dispersion of the instant invention consists essentially of (a) an anionic surfactant or dispersant; (b) the adhesive carbon black and/or graphite particles; (c) a pH adjuster, wherein the pH adjuster is a hydroxide; and (d) balance water, wherein the adhesive carbon black and/or graphite particles are milled in a milling process capable of producing small particle size and a tight particle size distribution of the carbon particles. By “consisting essentially of” what is meant is that the conductive carbon dispersion is free of any additional element that would detract from the ability of the carbon dispersion to adhere to the printed wiring board. In one preferred embodiment, the conductive carbon dispersion of the instant invention consists of the listed ingredients.

Having an alkaline pH is also important and the pH is preferably in the range of about 8 to about 13, more preferably in the range of about 8 to about 10. Higher pH causes more carbonate to be absorbed into the solution from carbon dioxide in the air, so excessively high pH is avoided for this reason. In a preferred embodiment, a pH adjuster may be used and suitable pH adjusters include hydroxides such as potassium hydroxide and sodium hydroxide. In contrast, certain prior art products use ammonia as a pH adjuster, which is a volatile pH adjuster and not preferred because it evaporates and makes control more difficult. Thus, in one embodiment, the carbon dispersion at least substantially does not include ammonia.

The liquid carbon dispersion is typically placed in a vessel and the printed circuit board is immersed in, sprayed with or otherwise contacted with the liquid carbon dispersion. The temperature of the liquid dispersion in an immersion bath should be maintained at between about 60° F. and about 95° F. and preferably between about 70° F. and about 80° F. during immersion. The period of immersion advantageously ranges from about 15 seconds to about 10 minutes, more preferably from about 30 seconds to 5 minutes.

The desired thickness of the carbon coating is a thickness that sufficient to allow for a copper or other metal film to be electroplated onto the printed circuit board in a direct plate process. The upper limit of the thickness is determined by the ability to remove the carbon coating from the copper surfaces. If the carbon does not come off of the copper surfaces, then defects in the circuit board can occur, including poor copper to copper contact in the innerlayers of the circuit board. This is also referred to as “interconnect defect.” In one embodiment, this thickness may be in the range of about 0.05 to about 0.25 microns.

However, as discussed above, what is important is that the thickness is sufficient to allow for metal plating in a direct plating process without any defects.

The problem of the adhesion of carbon particles to the surface of printed wiring boards can arise especially when a microetch spray etch step is performed prior to drying the coating. In many prior art processes, after coating a printed wiring board with carbon containing dispersion, the coating is dried prior to employing the spray etch for cleaning the copper surfaces. However, the inventors of the present invention have found that this order of steps may be varied and that a good result can be achieved if the microetching step is performed prior to the drying step.

On the other hand, a typical system used for performing a direct plating process is a horizontal processing machine and the order of the steps in the horizontal processing system cannot be easily changed or modified. So, it may not be possible to change the order of the steps in the process in which case, the drying step may necessarily need to be performed after the drying step. However, due in part to the careful selection of the high molecular weight conditioning agent and the properties of the carbon dispersion, including small particle size and close particle size distribution, the adhesion of the carbon coating composition to the substrate can be optimized.

In one embodiment, the printed wiring board is further contacted with compressed air to unplug any through-holes that may retain plugs of the dispersion.

The carbon black or graphite dispersion on the printed wiring board not only coats the drilled through hole surfaces, which is desirable, but also entirely coats the metal (i.e., copper) plate or foil surfaces, which is undesirable. Therefore, prior to subsequent operations, all of the carbon black or graphite must be removed from the copper (or other metal) plate and/or foil surfaces.

The removal of the carbon black or graphite, specifically from the copper (or other metal) surfaces including, especially, the rims of the drilled holes while leaving the coating intact on the glass fibers and epoxy surfaces of the hole walls is accomplished using a microetch step.

The process described herein also lowers the propensity to hole wall pullaway in which, after soldering or heat cycling, electroplated copper plated over the direct plating coating is pulled of the hole, slot or microvia wall surface. The increased adhesion of the carbon particles as a results of using the process described herein reduces or eliminates this problem.

Microetch solutions used to remove excess graphite and/or carbon black are typically based on oxidizing agents such as hydrogen peroxide or a persulfate, such as sodium persulfate. For example, one suitable microetch solution is a sodium persulfate-based microetch solution combined with sufficient sulfuric acid to make a microetch bath containing 100 to 300 grams of sodium persulfate per liter of deionized water and about 1 to 10% by weight sulfuric acid.

However, any etchant that is suitable for the metal being plated may be used in the practice of the invention. For example, for copper plating, sodium persulfate-based etchants, peroxide sulfuric-acid based etchants, copper chloride-based etchants, ferric-based etchants are all suitable for use. However, any oxidizer that is capable of oxidizing copper metal to copper ion is sufficient and is usable in the process described herein.

In one embodiment, the printed circuit board is contacted with the microetchant by spraying the microetchant and the microetchant may be sprayed at a pressure within the range of about 20 to about 50 psi, more preferably about 30 to about 40 psi and temperature within the range of about 20 to about 45° C., more preferably about 30 to about 35° C.

As described herein, the steps of the direct plating process can be performed in various orders. For example, the printed wiring board panels can be dried prior to or subsequent to the spray etching step. While it is generally preferred that the drying step take place after the spray etching step, in the case where the spray etch step is performed after the drying step, there is still a benefit achieved in increased adhesion.

After the microetch step and a subsequent water rinse, the printed wiring board may either proceed to a photo-imaging process and later be electroplated or be directly panel electroplated. The printed wiring board may be further cleaned with, for example, a citric acid or benzotriazole anti-tarnish solution or another acid cleaner solution, or both, after the above described microetch step. The thus treated printed wiring board is then ready for the electroplating operation which includes immersing the printed wiring board in a suitable electroplating bath to plate a copper (or other metal) coating on the through hole walls of the non-conducting layer.

As described herein, in one preferred embodiment, the carbon coating is not dried prior to etching. In addition, is also possible to perform the metal plating step as well without first drying the carbon coating.

After the etching step (or the etching and plating steps), the printed circuit board is dried for a period of time to remove water. In one embodiment, the printed circuit board is dried for a period of about 20 seconds to about 90 seconds, more preferably about 30 seconds to about 60 seconds at an elevated temperature. The elevated temperature may be between about 125 and about 200° F., more preferably between about 150 and 175° F.

The plated metal is typically copper. However, the present invention is not limited to copper plated and the plated metal may be, for example, nickel, rhodium, platinum, cobalt, gold, tin, lead, and alloys of any of the foregoing. Other metals would also be known to those skilled in the and can be plated using the process described herein.

The invention will now be discussed in relation to the following non-limiting examples.

### Example 1

A printed wiring board containing through-holes was processed as follows:
1) The printed wiring board was immersed into a conditioner bath with a high molecular weight polyquaternium compound with an average molecular weight of about 3.2 million, a pH buffer and a surfactant for 30 seconds at 95° F. and pH 9.0.
2) The circuit board was rinsed with tap water for 30 seconds.
3) The circuit board was immersed into a carbon black dispersion according to the invention. The particles were adherent carbon black particles having a particle size of a D-50 of 80 nm and a D-99 of 377 nm. The dispersant used was an ethoxylated phosphate ester. The colloid was prepared at 20% solids and then diluted to 3% solids for use, it had a pH of 9.2.
4) The circuit board was spray etched at 40 psi using 50 g/L sodium persulfate etch for 30 seconds. 15 micro inches of copper was etched off the copper surfaces.
5) The board was spray rinsed at 40 psi using tap water.
6) The board was directly electroplated with copper for 5 minutes at 20 A/ft² using a bath containing 80 g/L copper sulfate pentahydrate, 200 g/L sulfuric acid, 60 ppm chloride ions, and 1% PC606 additive (available from MacDermid Enthone Inc, Waterbury, CT).

Upon inspection of the copper plated printed circuit board, there were no pin holes in the plated copper deposit.

### Comparative Example 1

A printed wiring board containing through-holes was processed as follows:
1) The printed wiring board was immersed into a conditioner bath with a high molecular weight polyquaternium compound with an average molecular weight of about 3.2 million, a pH buffer and a surfactant for 30 seconds at 95° F. and pH 9.0.
2) The circuit board was rinsed with tap water for 30 seconds.
3) The circuit board was immersed into a carbon black dispersion prepared by mixing carbon Black powder with a surfactant which had a particle size of D-50 equal to 180 nm and a D-99 equal to 743 nm. The dispersion was prepared at 16.7% solids and then diluted to 3% solids for use, it had a pH of 9.2.
4) The circuit board was spray etched at 40 psi using 50 g/L sodium persulfate etch for 30 seconds. 15 micro inches of copper was etched off of the copper surfaces.
5) The board was spray rinsed at 40 psi using tap water.
6) The board was directly electroplated with copper for 5 minutes at 20 A/ft² using a bath containing 80 g/L copper sulfate pentahydrate, 200 g/L sulfuric acid, 60 ppm chloride ions, and 1% PC606 additive (available from MacDermid Enthone Inc, Waterbury, CT).

Upon inspection of the copper plated printed circuit board, there was substantially no plating in the holes of the circuit board because the carbon coating had been washed off during steps 4 and 5.

### Example 2

A printed wiring board containing through-holes was processed as follows:
1) The printed wiring board was immersed into a conditioner bath with a high molecular weight polyquaternium compound with an average molecular weight of about 3.2 million, a pH buffer and a surfactant for 30 seconds at 95° F. and pH 9.0.
2) The circuit board was rinsed with tap water for 30 seconds.
3) The circuit board was immersed into a graphite dispersion according to the invention prepared in such a way as to have a particle size of a D-50 of 237 nm and a D-99 of 1853 nm. The dispersant used was an ethoxylated phosphate ester. The colloid was prepared at 21% solids and then diluted to 3% solids for use, it had a pH of 9.2.
4) The circuit board was spray etched at 40 psi using 50 g/L sodium persulfate etch for 30 seconds. 15 micro inches of copper was etched off the copper surfaces.
5) The board was spray rinsed at 40 psi using tap water.
6) The board was directly electroplated with copper for 5 minutes at 20 A/ft² using a bath containing 80 g/L copper sulfate pentahydrate, 200 g/L sulfuric acid, 60 ppm chloride ions, and 1% PC606 additive (available from MacDermid Enthone Inc, Waterbury, CT).

Upon inspection of the copper plated printed circuit board, there were no pin holes in the plated copper deposit.

### Comparative Example 2

A printed wiring board containing through-holes was processed as follows:
1) The printed wiring board was immersed into a conditioner bath with a high molecular weight polyquaternium compound with an average molecular weight of about 3.2 million, a pH buffer and a surfactant for 30 seconds at 95° F. and pH 9.0.
2) The circuit board was rinsed with tap water for 30 seconds.
3) The circuit board was immersed into a graphite dispersion prepared by mixing graphite powder with a surfactant which had a particle size of D-50 equal to 1050 nm and a D-99 equal to 4288 nm. The dispersion was prepared at 22% solids and then diluted to 3% solids for use, it had a pH of 9.5
4) The circuit board was spray etched at 40 psi using 50 g/L sodium persulfate etch for 30 seconds. 15 micro inches of copper was etched off the copper surfaces.
5) The board was spray rinsed at 40 psi using tap water.
6) The board was directly electroplated with copper for 5 minutes at 20 A/ft² using a bath containing 80 g/L copper sulfate pentahydrate, 200 g/L sulfuric acid, 60 ppm chloride ions, and 1% PC606 additive (available from MacDermid Enthone Inc, Waterbury, CT).

Upon inspection of the copper plated printed circuit board, there was substantially no plating on the holes of the circuit board because the graphite coating had been washed off during steps 4 and 5.

### Example 3

A printed wiring board containing through-holes was processed as follows:
1) The printed wiring board was immersed into a conditioner bath with a high molecular weight polyquaternium compound with an average molecular weight of about 3.2 million, a pH buffer and a surfactant for 30 seconds at 95° F. and pH 9.0.
2) The circuit board was rinsed with tap water for 30 seconds.
3) The circuit board was immersed into a graphite dispersion according to the invention prepared in such a way as to have a particle size of a D-50 of 297 nm and a D-99 of 1968 nm. The dispersant used was an ethoxylated tristyrylphenol phosphate ester. The colloid was prepared at 19% solids and then diluted to 3% solids for use, it had a pH of 9.3.
4) The circuit board was spray etched at 40 psi using 50 g/L sodium persulfate etch for 30 seconds. 15 micro inches of copper was etched off the copper surfaces.
5) The board was spray rinsed at 40 psi using tap water.
6) The board was directly electroplated with copper for 5 minutes at 20 A/ft² using a bath containing 80 g/L copper sulfate pentahydrate, 200 g/L sulfuric acid, 60 ppm chloride ions, and 1% PC606 additive (available from MacDermid Enthone Inc, Waterbury, CT).

Upon inspection of the copper plated printed circuit board, there were no pin holes in the plated copper deposit.

### Comparative Example 3

A printed wiring board containing through-holes was processed as follows:
1. The printed wiring board was immersed into a conditioner bath with a high molecular weight polyquaternium compound with an average molecular weight of about 3.2 million, a pH buffer and a surfactant for 30 seconds at 95° F. and pH 9.0.
2. The circuit board was rinsed with tap water for 30 seconds.
3. The circuit board was immersed into a carbon black dispersion prepared by mixing carbon black powder with water and an oleyl hydroxyethyl imidazoline surfactant which had a particle size of D-50 equal to 385 nm and a D-99 equal to 1503 nm. The dispersion was prepared at 14% solids and then diluted to 3% solids for use, it had a pH of 9.2.
4. The circuit board was spray etched at 40 psi using 50 g/L sodium persulfate etch for 30 seconds. 15 micro inches of copper was etched off the copper surfaces.
5. The board was spray rinsed at 40 psi using tap water.
6. The board was directly electroplated with copper for 5 minutes at 20 A/ft² using a bath containing 80 g/L copper sulfate pentahydrate, 200 g/L sulfuric acid, 60 ppm chloride ions, and 1% PC606 additive (available from MacDermid Enthone Inc, Waterbury, CT).

Upon inspection of the copper plated printed circuit board, there was substantially no plating on the holes of the circuit board because the carbon black coating had been washed off during steps 4 and 5.

Thus, it can be seen that the process described herein produces a carbon dispersion that adheres more closely to the printed wiring board substrate which in turn produces an adherent copper deposit that has no pin holes or other defects in the deposit.

Finally, it should also be understood that the following claims are intended to cover all of the generic and specific features of the invention described herein and all statements of the scope of the invention that as a matter of language might fall there between.

1. A method of preparing a non-conductive substrate to allow metal plating thereon, the method comprising the steps of:
a) optionally, contacting the non-conductive substrate with a precleaner;
b) contacting the non-conductive substrate with a conditioner comprising a high molecular weight conditioning agent;
c) applying a liquid carbon-based dispersion to the conditioned non-conductive substrate to form a carbon/conditioner gel coating on the conditioned non-conductive substrate, wherein the carbon-based dispersion comprises adhesive carbon or graphite particles dispersed in a liquid solution, wherein the carbon particles coagulate onto the conditioned substrate to form a carbon/conditioner gel coating; and
d) etching the carbon/conditioner gel coated substrate;
wherein the adhesive carbon black or graphite particles in the liquid-carbon based dispersion have a small particle size and a tight particle size distribution.

2. The method according to claim 1, wherein the etching step is performed before the liquid carbon-based dispersion dries on the non-conductive substrate and the method further comprises the step of drying the substrate and carbon-based dispersion after step d) to form a conductive carbon coating on the substrate.

3. The method according to claim 2, further comprising the step of electroplating a conductive metal on the substrate after step d).

4. The method according to claim 1, wherein the conditioning agent is a polyquaternium compound.

5. The method according to claim 4, wherein the polyquaternium compound has a molecular weight of at least 1,000,000 g/mol.

6. The method according to claim 5, wherein the polyquaternium compound has a molecular weight of at least 2,000,000 g/mol.

7. The method according to claim 6, wherein the polyquaternium compound has a molecular weight of at least 3,000,000 g/mol.

8. The method according to claim 1, wherein the substrate comprises a printed circuit board or a printed wiring board.

9. The method according to claim 1, wherein the substrate is contacted with the conditioner by immersing the substrate in the conditioner for at least about 20 seconds.

10. The method according to claim 3, wherein the carbon-based dispersion is dried after the etching step and before the electroplating step.

11. The method according to claim 3, wherein the carbon-based dispersion is not dried before the etching step or the electroplating step.

12. The method according to claim 3, wherein the carbon-based dispersion is dried after the etching step and after the electroplating step.

13. The method according to claim 1, wherein the carbon-based dispersion comprises:
a. a dispersant;
b. optionally, a binder;
c. a source of conductive carbon, wherein the source of conductive carbon is selected from carbon black and/or graphite particles;
d. a pH adjuster, wherein the pH adjuster is a hydroxide; and
e. balance water, and
wherein the carbon black and/or graphite particles are milled in a milling process capable of producing adhesive carbon black and/or graphite particles exhibiting a small particle size and a tight particle size distribution.

14. The method according to claim 13, wherein the conductive carbon is graphite and the graphite particles exhibit a D50 of less than 350 nm and a D99 of less than 2500 nm.

15. The method according to claim 14, wherein the graphite particles exhibit a D50 of less than 300 nm.

16. The method according to claim 13, wherein the conductive carbon is carbon and the graphite particles exhibit a D50 of less than 100 nm and a D99 of less than 400 nm.

17. The method according to claim 13, wherein the dispersant is an anionic surfactant selected from the group consisting of ethoxylated phosphate esters, ethoxylated and propoxylated phosphate esters, ethoxylated tristyrylphenol phosphate esters, and combinations of one or more of the foregoing.

18. The method according to claim 1, wherein concentration of the carbon or graphite particles in the carbon-based dispersion is between about 2 and about 5% by weight.

19. The method according to claim 1, wherein the substrate is dried for about 20 to about 90 seconds at a temperature of between about 125 and about 200° F.

20. The method according to claim 19, wherein the substrate is dried for about 30 to about 60 seconds.

21. The method according to claim 19, wherein the substrate is dried at a temperature of between about 150 and about 175° F.

22. The method according to claim 1, wherein the metal portions of the substrate are etched with an etchant, the etchant being selected from the group consisting of sodium persulfate-based etchants, peroxide sulfuric-acid based etchants, copper chloride-based etchants, and ferric-based etchants.

23. A two-part gel coating composition for preparing a non-conductive substrate to allow metal plating thereon, the two-part gel coating comprising:
a. a conditioner comprising:
i. a polyquaternium compound having a molecular weight of greater than 1,000,000 g/mol;
ii. a pH buffer; and
iii. a surface tension reducing agent,
wherein the conditioner has a pH in the range of about 8 to about 10; and
b. a liquid carbon-based dispersion, wherein the liquid carbon-based dispersion comprises:
i. adhesive carbon or graphite particles dispersed in a dispersant, and
ii. a pH adjuster,
wherein the adhesive carbon black or graphite particles have a small particle size and a tight particle size distribution, and where the pH of the liquid carbon dispersion is in a range of about 8 to about 10;
wherein when the conditioner and the liquid carbon-based dispersion are sequentially applied to the non-conductive substrate, an adherent carbon/conditioner gel coating is formed on the surface of the non-conductive substrate.

24. The two-part gel coating composition according to claim 23, wherein the conductive carbon is graphite and the graphite particles exhibit a D50 of less than 350 nm and a D99 of less than 2500 nm.

25. The two-part gel coating composition according to claim 24, wherein the graphite particles exhibit a D50 of less than 300 nm.

26. The two-part gel coating composition according to claim 23, wherein the conductive carbon is carbon and the graphite particles exhibit a D50 of less than 100 nm and a D99 of less than 400 nm.

27. The two-part gel coating composition according to claim 23, wherein the pH adjuster of the liquid carbon-based dispersion is a hydroxide.

28. A printed circuit board comprising a plurality of through-holes,
wherein the through-holes are prepared for electroplating by applying the two-part gel coating composition according to claim 23 to form an adherent carbon/conditioner gel coating on surfaces of the through-holes.
